(19) United States
(12) Patent Application Publication
(10) Pub. No.: US 2012/0032145 A1
(43) Pub. Date: Feb. 9, 2012

(54) DETECTION DEVICE, LIGHT-RECEIVING ELEMENT ARRAY, SEMICONDUCTOR CHIP, METHOD FOR MANUFACTURING THE SAME, AND OPTICAL SENSOR APPARATUS

(75) Inventors: Youichi NAGAI, Osaka-shi (JP); Hiroki MORI, Osaka-shi (JP)

(73) Assignee: SUMITOMO ELECTRIC INDUSTRIES, LTD., Osaka-shi (JP)

(21) Appl. No.: 13/197,272

(22) Filed: Aug. 3, 2011

(30) Foreign Application Priority Data
Aug. 3, 2010 (JP) 2010-174607

(51) Int. Cl. H01L 31/0352; H01L 31/18; H01L 23/485; B82Y 20/00

(52) U.S. Cl. 257/14; 257/737; 438/73; 977/954; 257/E31.033; 257/E23.021

(57) ABSTRACT

A detection device includes a light-receiving element array and a read-out integrated circuit (CMOS), bumps of the light-receiving element array being bonded to bumps of the read-out integrated circuit, and at least one of the light-receiving element array and the read-out integrated circuit having a concaved surface which faces the other. The bonded bumps positioned in a region near the periphery of the arrangement region of the bonded bumps have a larger diameter and a lower height than those of the bumps positioned in a central region. Therefore, it is possible to prevent bonding failure and insulation failure in the bumps from occurring due to a difference in coefficient of thermal expansion, while securing a small size and low cost.

### BACKGROUND OF THE INVENTION

1. Field of the Invention

The present invention relates to a detection device including a light-receiving element array in which electrodes of pixels are arranged and a read-out integrated circuit in which read-out electrodes for reading out charges from the electrodes are arranged, the light-receiving element array and the read-out integrated circuit being bonded to each other, a light-receiving element array, a semiconductor chip, and an optical sensor apparatus, and methods for manufacturing the detection device, the light-receiving element array, and the read-out integrated circuit.

2. Description of the Related Art

Since the near-infrared region corresponds to an absorption spectral region related to living bodies of plants and animals and environments, near-infrared detectors using Group III-V compound semiconductors in absorption layers are actively developed. As the detectors, read-out integrated circuits (ROIC) including complementary metal-oxide semiconductors (CMOS) formed on silicon are used, and the detection device is called “hybrid type detection devices” because silicon and compound semiconductors are combined. In general, a problem described below has occurred in thermal compression bonding between electrodes of a light-receiving element array and a read-out integrated circuit through bumps. In forming bumps on a module substrate and in mounting on a mother substrate, the bumps are deformed due to a difference in coefficient of thermal expansion between silicon and a compound semiconductor, thereby causing bonding failure and insulation failure in the bumps. In particular, in a two-dimensional arrangement of pixels, the pixels in an outer region are subjected to larger thermal stress, and thus the above-described problem significantly occurs.

In order to resolve this problem, many proposals have been made. For example, for a hybrid type image pickup device including HgCdTe (light-receiving element array) and silicon (ROIC), there has been proposed a structure in which a germanium dummy substrate is disposed at the rear of a silicon substrate in order to achieve uniform thermal expansion (Japanese Unexamined Patent Application Publication No. 8-255887). In addition, for a hybrid type image pickup device, there has been proposed a structure in which reinforcing bumps for reinforcement are disposed outside the corner pixels (thermal stress is concentrated) in a two-dimensional rectangular arrangement (Japanese Unexamined Patent Application Publication No. 8-139299). Further, not for a hybrid type detection device, there has been proposed a structure in which lands in an outer region have a larger size, and conversely, bumps in the outer region have a smaller size in order to prevent warp of a printed circuit board (Japanese Unexamined Patent Application Publication No. 2007-109933).

A portion where stress due to a difference in thermal expansion is greatly concentrated may be removed by the above-described structures. However, for example, the cost of preparing, incorporating, and fixing the dummy substrate increases. In addition, when an InP-based semiconductor is used on the sensor side, it is difficult to select a material having a proper coefficient of thermal expansion for the dummy substrate. Further, the expansion and shrink of silicon is suppressed, thereby causing deterioration in the performance of IC circuits. With some materials for the dummy substrate, heat radiation from silicon IC to a package is inhibited.

In the structure in which a reinforcing bump is disposed at each of the corners, an excessive space is required, and thus the whole size of a chip is increased. Therefore, it is necessary to increase the sizes of peripheral devices such as ROIC, a package, a peltier element, etc. with an increase in chip size, thereby causing an increase in cost. Further, in spite of a small degree of reinforcement, reinforcement by providing a plurality of reinforcing bumps of the same size as bond bumps needlessly increases the number of bumps, thereby unpractically decreasing the commercial value.

In a hybrid type detection device, pixels are required to have the same size in order to achieve uniform sensitivity. Further, the pixel pitch is decreased to a limit where no interference is produced between pixels according to the size of pixels. Such a device, unlike a printed board, is subjected to large restriction by changing the bump size. The restriction is reduced by increasing the whole size of the device, but the cost is increased by increasing the size of the device.

### SUMMARY OF THE INVENTION

Accordingly, it is an object of the present invention to provide a detection device, a light-receiving element array, and a semiconductor chip, which are capable of preventing bonding failure and insulation failure in bumps while securing a small size and low cost, these failures being due to a difference in a coefficient of thermal expansion, and also provide methods for manufacturing the same and an optical sensor apparatus.

A detection device according to the present invention includes a light-receiving element array including pixel electrodes arranged therein and a bump disposed on each of the pixel electrodes, and a read-out integrated circuit (ROIC) including read-out electrodes arranged therein and a bump disposed on each of the read-out electrodes, the bumps of the light-receiving element array being bonded to the bumps of the read-out integrated circuit.

In the detection device, at least one of the light-receiving element array and the read-out integrated circuit has a concaved surface which faces the other. In addition, among the bonded bumps, the bonded bumps disposed in a region near the periphery of the arrangement region have a larger diameter and a lower height than the bonded bumps disposed in a central region.

In the above-described configuration, the bumps in the region near the periphery where large thermal stress is produced have a larger diameter and a lower height than the bumps in the central region, thereby causing little deformation even when bearing a high load. Therefore, the bonding failure and insulation failure between the bumps can be prevented. As a result, a high-quality detection device can be provided. In addition, the form in which the bonded bumps disposed in a region near the periphery of the arrangement region have a larger diameter and a lower height than the bonded bumps disposed in a central region typically includes a configuration in which the bonded bumps increases in diameter and decreases in height from the central region to the region near the periphery, and can also include many other configurations.

In the detection device, the above-described bump configuration may be provided to one of the light-receiving element array and the read-out integrated circuit. Alternatively, the above-described bump configuration may be provided to both the light-receiving element array and the read-out integrated circuit. In this case, the load force of the bumps in the region near the periphery can be further increased.

Here, the height of the bonded bumps is the mean distance between the pixel electrode surfaces and the read-out electrode surfaces. The height of the bumps before bonding described below is the distance between the electrode surfaces on which the bumps are positioned and the tops of the bumps. Since some of the bonded bumps are inclined with respect to the electrode surfaces (in particular, in the region near the periphery), the distances are averaged along the periphery of each of the bumps. For example, the average is determined using the maximum height and the minimum height. In addition, the term “low height” may be expressed by the term “short length”. The thickness or diameter is measured at a plurality of points of each of the bonded bumps. In the central region and the region near the periphery, a plurality of bumps within the corresponding regions are measured, and an average of the plurality of bumps is determined using an average of each of the bumps.

A light-receiving element array includes a semiconductor substrate and an epitaxial stacked structure formed on the semiconductor substrate and including an absorption layer. A pixel region where the pixel electrodes make ohmic contact is formed by selective diffusion of impurity from the surface of the epitaxial stacked structure so as to form pn junction for each of the pixels. The absorption layer can satisfy the condition of lattice matching with the semiconductor substrate, |‘a’−ao|/ao≦0.002 (wherein ‘a’ is a lattice parameter of the absorption layer and ao is a lattice parameter of the semiconductor substrate). Therefore, a near-infrared detection device in which pixel failures particularly in a region near the periphery are suppressed can be provided using a light-receiving element array with a low dark current.

The absorption layer is configured to have a multi-quantum well (MQW) structure. A diffusion concentration distribution control layer is disposed in contact with the pixel electrode-side surface of the absorption layer, and the diffusion concentration distribution control layer is made of a material with a smaller band gap than that of the semiconductor substrate. In the diffusion concentration distribution control layer, the concentration of the impurity element decreases stepwisely from a concentration region on the pixel electrode side in the thickness direction to a low concentration region on the semiconductor substrate side in the thickness direction, Consequently, a high-quality detection device with few pixel failures can be provided using a light-receiving element array which uses MQW with good crystal quality and which has light sensitivity in a wavelength region characteristic of the MQW, for example, the near infrared wavelength region, and suppressed dark current.

The semiconductor substrate is an InP substrate, the multi-quantum well structure is type 2 composed of any one of GaAsSb/InGaAs, GaAsSb/InGaAsN, GaAsSb/InGaAsNP, and GaAsSb/InGaAsNSb, and the band gap wavelength including a sub-band is 1.65 μm or more and 3 μm or less. The impurity element is zinc (Zn). The diffusion concentration distribution control layer is composed of InGaAs, and the impurity concentration in the absorption layer is 5e16 cm⁻³ or less. In the diffusion concentration distribution control layer, the impurity concentration decreases from 1e18 cm⁻³ or more and 9.9e18 cm⁻³ or less in the pixel electrode-side region to 5e16 cm⁻³ or less in the InP substrate-side region. Consequently, a high-quality detection device with no pixel failure can be provided using a light-receiving element array having light sensitivity in the near infrared wavelength region and low dark current. In this wavelength region, absorption spectra of various substances such as living bodies, environmental atmospheres, etc. are present. When the light-receiving elements are used for a monitoring apparatus with night vision, a biological component detection device, a moisture detector, a food quality examination device, and an environment monitoring apparatus, important data in various fields can be detected.

In the light-receiving element array according to the present invention, a bump is disposed on each of the arranged pixel electrodes. In the light-receiving element array, an epitaxial layer on which the pixel electrodes are arranged has a concaved surface, and the top surfaces of the bumps are arranged in a plane. In addition, the tops of the bumps disposed in a region near the periphery of the arrangement region have a larger diameter and a lower height than the bumps disposed in a central region.

In the detection device assembled into the above-described configuration, pixel failures which are easily produced, particularly, in the region near the periphery can be decreased.

When the tops of the bumps are regarded as substantially circles, the average diameter is considered as the diameter of the tops, while the tops of the bumps are not regarded as circles, the average is determined using the major diameter and minor diameter. In the case of an irregular shape, the shape is approximated by an ellipsoidal shape or the like, and the average is determined using the major diameter and minor diameter. The expression “the top surfaces of the bumps are arranged in a plane” represents that all top surfaces are placed on a plane so as to form a plane.

The height of the bumps is a distance between the pixel electrode surfaces and the top surfaces bonded to bumps of the other member. Since the top surfaces of some of the bumps before bonding are inclined with respect to the electrode surfaces (in particular, in the region near the periphery), the distances are averaged along the periphery of each of the bumps. For example, the average is determined using the maximum height and the minimum height. In addition, the term “low height” may be expressed by the term “short length”.

These bumps are bumps before bonding but have the same configuration as the bonded bumps. That is, the configuration in which the tops of the bumps disposed in a region near the periphery of the arrangement region have a larger diameter and a lower height than the bumps disposed in a central region typically includes a configuration in which the bumps increases in diameter and decreases in height from the central region to the region near the periphery, and can also include many other configurations.

A light-receiving element array includes a semiconductor substrate and an epitaxial stacked structure formed on the semiconductor substrate and including an absorption layer. A pixel region where the pixel electrodes make ohmic contact is formed by selective diffusion of impurity from the surface of the epitaxial stacked structure so as to form pn junction for each of the pixels. The absorption layer can satisfy the condition of lattice matching with the semiconductor substrate, |‘a’−ao|/ao≦0.002 (wherein ‘a’ is a lattice parameter of the absorption layer and ao is a lattice parameter of the semiconductor substrate).

Therefore, a light-receiving element array with a low dark current can be used. By using the light-receiving element array, a high-quality detection device in which pixel failures in a region near the periphery are suppressed can be provided.

The absorption layer is configured to have a multi-quantum well (MQW) structure. A diffusion concentration distribution control layer is disposed in contact with the pixel electrode-side surface of the absorption layer, and the diffusion concentration distribution control layer is made of a material with a smaller band gap than that of the semiconductor substrate. In the diffusion concentration distribution control layer, the concentration of the impurity element decreases stepwisely from a concentration region on the pixel electrode side in the thickness direction to a low concentration region on the semiconductor substrate side in the thickness direction.

Consequently, a light-receiving element array using MQW with good crystal quality and a low dark current can be provided. By using the light-receiving element array, a high-quality detection device having suppressed pixel connection failures and sensitivity in the wavelength region characteristic of the MQW can be provided.

The semiconductor substrate is an InP substrate, the multi-quantum well structure is type 2 composed of any one of GaAsSb/InGaAs, GaAsSb/InGaAsN, GaAsSb/InGaAsNP, and GaAsSb/InGaAsNSb, and the band gap wavelength including a sub-band is 1.65 μm or more and 3 μm or less. The impurity element is zinc (Zn). The diffusion concentration distribution control layer is composed of InGaAs, and the impurity concentration in the absorption layer is 5e16 cm⁻³ or less. In the diffusion concentration distribution control layer, the impurity concentration may decrease from 1e18 cm⁻³ or more and 9.9e18 cm⁻³ or less in the pixel electrode-side region to 5e16 cm⁻³ or less in the InP substrate-side region.

Consequently, a light-receiving element array having light sensitivity in the near infrared wavelength region and a low dark current can be provided. As a result, a high-quality detection device with no pixel connection failure can be provided.

A semiconductor chip according to the present invention includes electrodes arranged therein and a bump disposed on each of the electrodes. The semiconductor chip further includes an epitaxial layer on which the electrodes are arranged and which has a concaved surface. The pumps provided on the electrodes have flat top surfaces and the top surfaces of the bumps disposed in a region near the periphery have a larger diameter and a lower height than those of the bumps disposed in a central region.

This configuration can prevent connection failure due to thermal stress in a (detection) device in which electrodes arranged at a short pitch are conductively connected through the bumps disposed on the respective electrodes. Therefore, high-quality signal transfer can be realized without defects at points corresponding to the electrodes. As described later, the semiconductor chip of the present invention may be any one of a read-out integrated circuit and a light-receiving element array. However, unless a specific device is described, the semiconductor chip is assumed as the read-out integrated circuit.

When the semiconductor chip is assumed as the read-out integrated circuit (ROIC), read-out electrodes can be used as the electrodes. Therefore, a good detection device with few connection failures can be provided by combination with a light-receiving element array.

An optical sensor apparatus of the present invention includes any one of the above-described detection devices, any one of the above-described light-receiving element arrays, and any one of the above-described semiconductor chips.

Thus, an optical sensor apparatus having high sensitivity in the near infrared region can be provided by combination with an optical element such as a diffracting grating.

The optical sensor apparatus of the present invention is combined with an optical element, for example, a spectroscope or a lens optical system, and can be used for wavelength distribution measurement, used as an image pickup device, and used for providing many useful practical products. Specific examples of the optical sensor apparatus include (i) an image pickup device for visibility support or monitoring, (ii) examination devices such as a biological component detection device, a moisture detector, and a food quality examination device, and (iii) an environment monitoring apparatus for determining components of combustion gas. In brief, the optical sensor apparatus may be any apparatus including a combination of the light-receiving element, the light-receiving element array, or the hybrid type detection device and an optical element such as a lens, a filter, an optical fiber, a diffracting grating, or a spectral lens. When screen display or determination is performed, a microcomputer and a screen display device are further added.

A method for manufacturing a light-receiving element array of the present invention is to manufacture a light-receiving element array including pixel electrodes arranged therein. The manufacturing method includes a step of growing an epitaxial stacked structure on a semiconductor wafer at a temperature of 450° C. or more and 650° C. or less and then cooling the structure to warp the semiconductor wafer along a concaved surface of the epitaxial stacked structure, a step of forming the pixel electrodes on the surface of the epitaxial stacked structure, a step of disposing a material of bumps with the same shape and same weight for the pixel electrodes in order to form the bumps on the pixel electrodes, a step of individualizing the semiconductor wafer to form light-receiving element array chips, and a step of placing a plate on the bumps of the light-receiving element arrays and applying a pressure so that the top surfaces of the bumps are arranged in parallel with the surface of the plate.

According to the method, the bumps in a region near the periphery of the electrode arrangement in the light-receiving element array can be made to have a larger diameter and a lower height than the bumps in a central region. In addition, the top surfaces of the bumps form a plane, and thus the bumps (electrodes) arranged at a short pitch and a high density can be securely easily connected to bumps of the other member to be bonded without mismatch therebetween. When the bumps have convexly projecting tops, mismatch occurs due to even small positional deviation of the tops, thereby easily producing connection failure. When the top surfaces are pressed with the plate, the top surfaces are made planar and thus easily form connection with the bumps of the other member to bonded even with small positional deviation.

A method for manufacturing a detection device of the present invention is to manufacture a detection device including a light-receiving element array manufactured by the above-described manufacturing method. The manufacturing method for a detection device includes preparing a read-out integrated circuit (ROIC) including read-out electrodes corresponding to the respective pixel electrodes of the light-receiving element array, forming a bump on each of the read-out electrodes, and bonding the bump of each of the pixel electrodes of the light-receiving element array to the bump of each of the read-out electrodes of the read-out integrated circuit by pressure bonding or heat melting.

The expression “the read-out electrodes corresponding to the respective pixel electrodes” represents that both electrodes arranged are aligned with each other.

Therefore, in the light-receiving element array, at least the bumps in a region near the periphery of the electrode arrangement are made to have a larger diameter and a lower height than the bumps in a central region. Thus, in a detection device including bonded bumps, even when large thermal stress is produced in the region rear the periphery, deformation or the like due to the load of the stress can be suppressed, resulting in the suppression of connection failure.

The method for manufacturing a detection device includes, after forming a bump on each of the read-out electrodes, disposing the read-out integrated circuit on a support having a concaved surface, placing a plate on the bumps of the read-out electrodes, and applying pressure to bond the bump of each of the pixel electrodes of the light-receiving element array to the bump of each of the read-out electrodes of the read-out integrated circuit.

Therefore, in both the light-receiving element array and the read-out integrated circuit, the bumps in a region near the periphery can be made to have a larger diameter and a lower height than the bumps in a central region. As a result, the resistance to thermal stress can be further increased, and thus high-quality pixel information without defects can be provided.

The concaved surface of the support can be formed so as to rise at a rate of 2 μm to 10 μm per 10 mm in a radial direction from the center to the periphery in such a manner that an outer portion more rises than a central portion. Therefore, the bumps can be arranged in a configuration in which the bumps are increased in diameter and decreased in length closer to the outer periphery, while the read-out integrated circuit using silicon is warped concavely. This is similar to the warp and the bump configuration of the light-receiving element array, and both the light-receiving element array and the read-out integrated circuit have the resistance to thermal stress, thereby providing a detection device having higher resistance to stress.

A method for manufacturing a read-out integrated circuit of the present invention is to manufacture a read-out integrated circuit formed on a semiconductor substrate and including read-out electrodes therein. This manufacturing method includes a step of forming a bump on each of the electrodes of the read-out integrated circuit, a step of preparing a support having a concaved surface, and a step of disposing the read-out integrated circuit having the bumps formed thereon on the support and pushing the bumps by applying pressure to a plate disposed thereon.

Therefore, the bumps can be arranged in a configuration in which the bumps are increased in diameter and decreased in length closer to the outer periphery, while the read-out integrated circuit using silicon is warped concavely. This is similar to the warp and the bump configuration of the light-receiving element array, and at least the read-out integrated circuit can be made resistant to thermal stress.

Another method for manufacturing a detection device of the present invention is to manufacture a detection circuit using a concavely warped read-out integrated circuit manufactured by the above-described method for manufacturing a read-out integrated circuit. This manufacturing method may include preparing a light-receiving element array having pixel electrodes which correspond to the read-out electrodes of the read-out integrated circuit, forming a bump on each of the pixel electrodes, and bonding the bumps of the read-out electrodes of the read-out integrated circuit to the bumps of the pixel electrodes of the light-receiving element array by pressure bonding or heat melting.

Therefore, a detection device can be manufactured by using a read-out integrated circuit resistance to, at least, thermal stress. The light-receiving element array may have a similar bump configuration having resistance to thermal stress.

The detection device etc. of the present invention are capable of preventing bump bonding failure and insulation failure, which are due to a difference in coefficient of thermal expansion, while securing a small size and low cost, thereby permitting transfer of high-quality pixel signals without defects.

In particular, the present invention is aimed at a detection device etc. having light sensitivity in the near infrared wavelength region and can provide high-definition and high-quality information in examination of living bodies, water, food, environmental atmospheres, and the like.

### BRIEF DESCRIPTION OF THE DRAWINGS

FIG. 1 is a drawing showing a light-receiving element array according to a first embodiment of the present invention.

FIG. 2A is a drawing showing a detection device manufactured by combining the light-receiving element array shown in FIG. 1 and a read-out integrated circuit formed on a silicon substrate.

FIG. 2B is a drawing showing a read-out integrated circuit of a detection device manufactured by combining the light-receiving element array shown in FIG. 1 and the read-out integrated circuit formed on a silicon substrate.

FIG. 3A is a drawing showing a specific structure of a detection device of a type in which grand electrodes are connected through a wiring circuit.

FIG. 3B is a drawing showing a specific structure of a detection device of a type in which grand electrodes are opposed to each other and bonded through a bump.

FIG. 4A is a drawing showing a state in which an epitaxial stacked structure is grown in a method for manufacturing a detection device.

FIG. 4B is a drawing showing a state in which an epitaxial stacked structure is warped by cooling in a method for manufacturing a detection device.

FIG. 5 is a drawing showing a state in which bumps are arranged after selective diffusion of impurity and electrode formation on an InP substrate whose rear surface is polished.

FIG. 6 is a drawing showing a state in which bumps are arranged after selective diffusion of impurity and electrode formation on an InP substrate which is maintained in a horizontal position by using a support member without being polished.

FIG. 7 is a drawing showing an epitaxial wafer.

FIG. 8 is a drawing showing an individual light-receiving element array chip.

FIG. 9A is a drawing showing the results of warp measurement in the case where a warp at the periphery is 2 μm (Max).

FIG. 9B is a drawing showing the results of warp measurement in the case where a warp at the periphery is 5 μm (Max).

FIG. 10 is a drawing showing a state in which bumps of a light-receiving element array are planarized.

FIG. 11 is a drawing showing simulation results which indicate the relation between the height of bumps (after planarization) and the diameter of bumps and adjacent-bump spacing after planarization.

FIG. 12 is a drawing showing a state in which bumps of a read-out integrated circuit are bonded to bumps of a light-receiving element array with a bonding device.

FIG. 13A is a drawing showing a read-out integrated circuit (CMOS) formed on silicon and entirely warped in a bowl-like shape along a concaved surface according to a second embodiment of the present invention.

FIG. 13B is a drawing showing a read-out integrated circuit (CMOS) formed on silicon and restored to be flat without being entirely warped according to the second embodiment of the present invention.

FIG. 14 is a drawing showing a detection device including combination of a light-receiving element array and the CMOS shown in FIG. 13A.

FIG. 15A is a drawing showing a method for manufacturing the read-out integrated circuit shown in FIG. 13A.

FIG. 15B is a drawing showing a method for manufacturing the read-out integrated circuit shown in FIG. 13A.

FIG. 16 is a drawing showing a detection device according to a third embodiment of the present invention.

FIG. 17 is a drawing showing a method for manufacturing a detection device using a bonding device according to an embodiment of the present invention.

### DESCRIPTION OF THE PREFERRED EMBODIMENTS

### First Embodiment

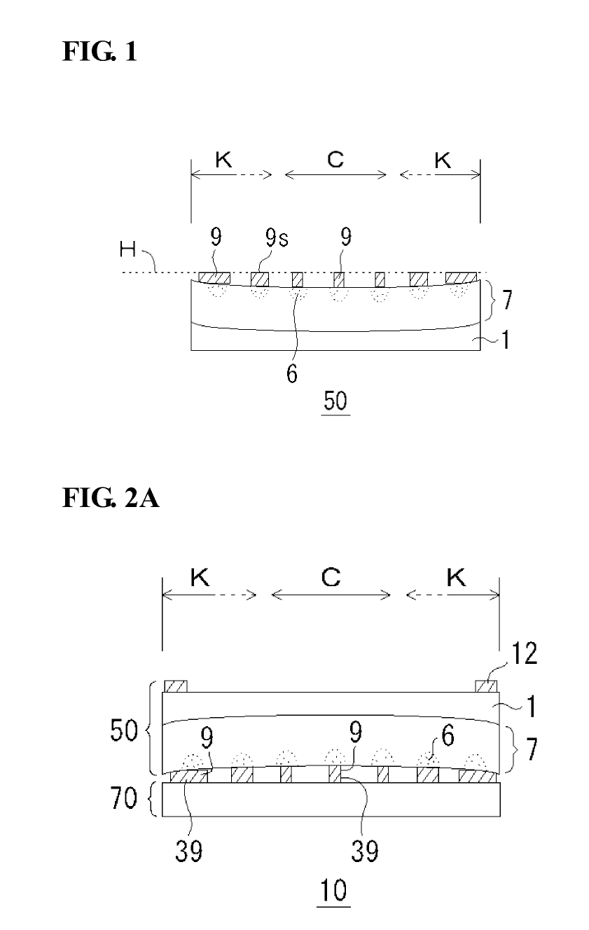

FIG. 1 is a drawing showing a light-receiving element array (sensor chip) 50 according to a first embodiment of the present invention. The light-receiving element array 50 includes an InP substrate 1 and an InP-based epitaxial stacked structure 7 formed on the InP substrate 1 and containing an absorption layer (not shown). In addition, p-type regions 6 are separately formed by selective diffusion of zinc (Zn) as p-type impurity from the surface of the InP epitaxial stacked structure 7. Each of the p-type regions serves as a core of a pixel. Further, a pixel electrode (p-side electrode) not shown is formed to make ohmic contact in each of the p-type regions 6, and bumps 9 are formed on the respective pixel electrodes. The characteristics of the light-receiving element array 50 according to this embodiment are as follows.

(1) The epitaxial stacked structure 7 has an upwardly (outwardly) concaved surface.

(2) The bumps 9 in a region K near the periphery have a larger diameter and a lower height than those of the bumps in a central region C. The height is a distance from the electrode surfaces to the tops 9s of the bumps 9.

(3) The tops 9s of the bumps 9 are planar and all arranged in a plane H. That is, the tops 9s of all bumps 9 are placed on the plane H.

Although the InP substrate 1 is planarized by polishing, the InP substrate 1 may be supported horizontally, without being planarized, by support members separately arranged so that the warp of the rear surface does not affect horizontal support.

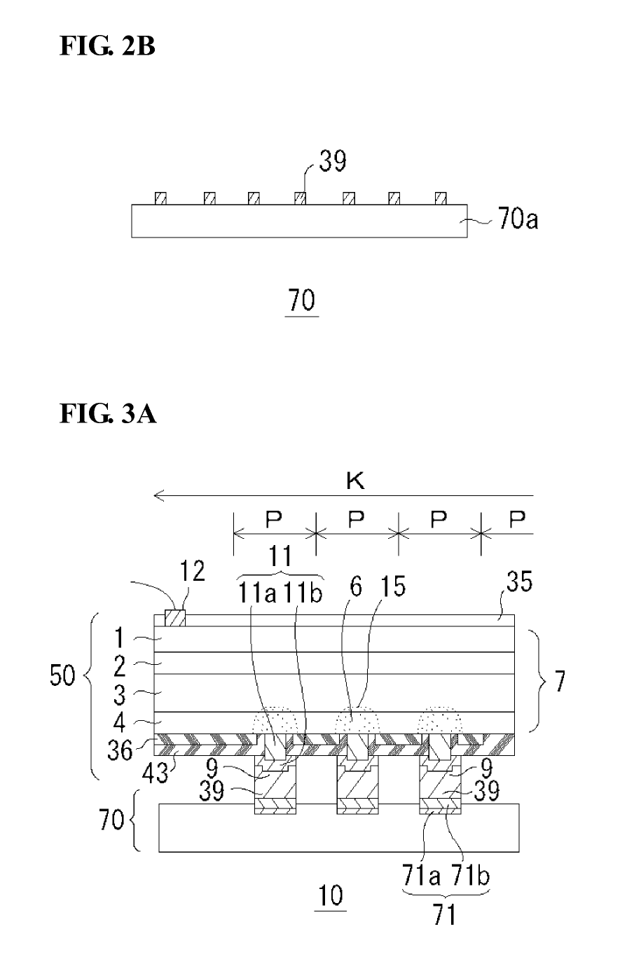

FIG. 2A is a drawing showing a detection device 10 manufactured by combining the light-receiving element array 50 shown in FIG. 1 with a CMOS 70 serving as a read-out integrated circuit formed on a silicon substrate. The CMOS 70 is shown in FIG. 2B. In the CMOS 70, bumps 39 are formed in the same shape using the same material. However, the bumps 9 of the light-receiving element array 50 have a configuration shown in FIG. 1, and thus the bonded bumps 9, 39 bonded by pressure bonding or heat melting in a region K near the periphery have a larger diameter and a lower height than those of the bumps 9, 39 in a central region C. This results in the following advantages.

(E1) Even when thermal stress occurs due to a difference in coefficient of thermal expansion between silicon and InP, the bonded bumps 9, 39 in the region K near the periphery where large thermal stress is produced to have a larger diameter and a lower height and can thus bear the stress with no deformation or suppressed deformation. Therefore, connection failure and insulation failure by the deformation due to thermal stress can be prevented.

(E2) Since the tops 9s of the bumps 9 of the light-receiving element array 50 are made planar, mismatch little occurs from the bumps 39 of the other member (CMOS 70) to be bonded thereto. For example, when bumps having sharp ends are bonded by pressure bonding, connection failure and insulation failure (contact with the adjacent bumps) are produced by only small positional deviation. Since the tops 9s of the bumps 9 of the light-receiving element array 50 are made planar, such positional deviation can be prevented.

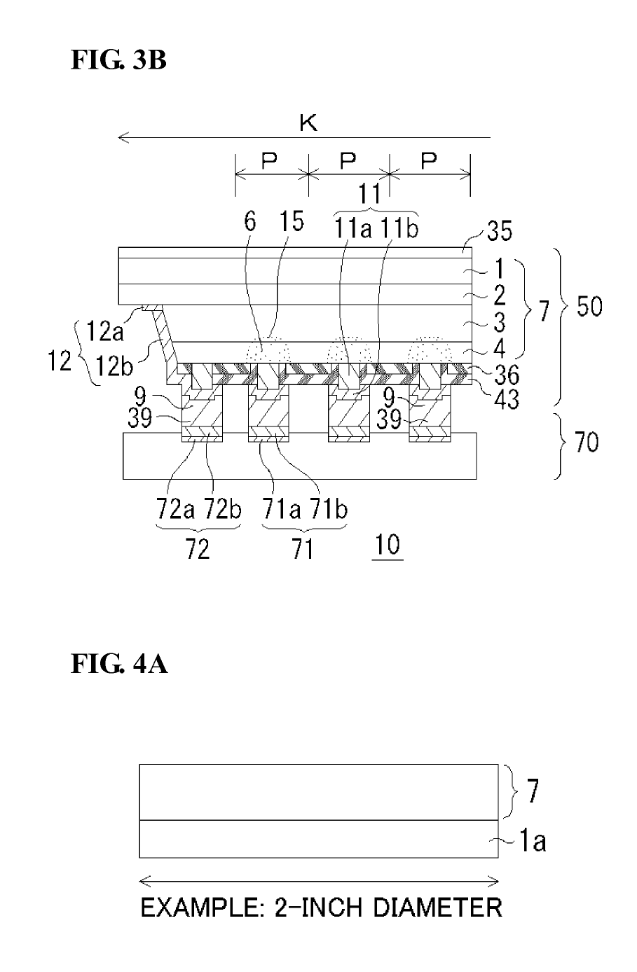

FIGS. 3A and 3B are drawings each specifically showing the light-receiving element array 50 constituting the detection device 10 shown in FIG. 2A. In FIG. 3A, the light-receiving element array 50 is formed in the epitaxial stacked structure 7 including an n-type InP substrate 1, an n-type InP buffer layer or n-type InGaAs buffer layer 2, an absorption (light absorption layer) 3, and an InP cap layer 4. In each pixel P, the p-type region 6 is formed to extend to the absorption layer 3 by selective diffusion of p-type impurity zinc (Zn) from the InP cap layer 4, thereby forming a pn junction at the end of the p-type region 6. The p-type regions extend to the absorption layer 3, and the pn junctions 15 are positioned in the absorption layer 3. The p-type region 6 constituting a main component of a light-receiving element of each of the pixels P is separated from the adjacent p-type region by a region without selective diffusion. Therefore, the light-receiving element array 50 with a low dark current can be provided using a simple structure without forming a mesa structure or the like.

Each of the p-type regions 6 makes ohmic contact with a p-type electrode 11, i.e., a pixel electrode 11, and conductive connection is made between the pixel electrode 11 and each of the bonded bumps 9. The pixel electrodes 11 each include an electrode portion 11a in ohmic contact with the InP cap layer 4 and a cover metal 11b which covers the electrode portion 11a. Each of the bumps 9 is formed on the cover metal 11b. The light-receiving element unit including the p-type region 6 and the pixel electrode 11 corresponds to each of the pixels P. An n-type electrode 12 which provides a common grand potential to the pixel electrodes 11 is in ohmic contact with the rear surface of the n-type InP substrate 1.

In addition, a SiON film is disposed as an antireflection film 35 on the rear surface serving as an incidence surface of the InP substrate 1 on which light is incident. A SiN selective diffusion mask pattern 36 used for forming the p-type regions 6 by selective diffusion is allowed to remain as it is. Further, a passivation film 43 is provided to cover the apertures of the selective diffusion mask pattern 36 or the surface of the InP cap layer 4 and the selective diffusion mask pattern 36.

On the other hand, in the CMOS 70 constituting ROIC, a read-out electrode 71 including a pad 71a and a cover metal 71b is formed at a position corresponding to each of the pixel electrodes 11. The bump 9 on each of the pixel electrodes 11 is pressure-bonded to the bump 39 on each of the read-out electrodes 71 to form the bonded bump 9, 39.

In FIG. 3A, the absorption layer 3 of the light-receiving element array 50 may be any absorption layer as long as it has light sensitivity in a wavelength region of wavelengths of 1 μm to 3 μm. For example, any one of InGaAsNP, InGaAsNSb, and InGaAsN can be used.

In particular, when sensitivity is imparted to a long-wavelength side of the wavelength region, the absorption layer 3 may be composed of type 2 MQW. In the absorption layer 3 composed of type 2 MQW, when zinc (Zn) as p-type impurity is diffused, the Zn concentration in the MQW is preferably suppressed to a predetermined level or less in order to secure good crystal quality. Therefore, a diffusion concentration distribution control layer (not shown) is provided on the InP cap layer 4 side. In FIG. 3A, when the absorption layer 3 is composed of MQW, the diffusion concentration distribution control layer is considered to be contained on the InP cap layer 4 side in the absorption layer 3. When the diffusion concentration distribution control layer (not shown) is interposed between the absorption layer 3 and the cap layer 4, the diffusion concentration distribution control layer is formed of InGaAs with which the electric resistance is little increased even when there is a portion (a predetermined portion on the absorption layer side in the thickness direction) with a low impurity concentration in the thickness direction because of the relatively low band gap energy. By inserting the diffusion concentration distribution control layer, type 2 MQW having good crystal quality can be achieved. As the MQW, GaAsSb/InGaAs, GaAsSb/InGaAsN, GaAsSb/InGaAsNP, or GaAsSb/InGaAsNSb may be used. Such type 2 MQW has a band gap wavelength of 1.65 μm or more and 3 μm or less including a sub-band and has light sensitivity in the above-described wavelength region.

When light is absorbed, a reverse bias voltage is applied between the pixel electrodes 11 and the ground electrode 12. By applying the reverse bias voltage, a wider depletion layer is produced on the low n-type impurity concentration side (n-type impurity background). The impurity background in the MQW absorption layer 3 may be about 5e16 cm⁻³ or less in terms of n-type impurity concentration (carrier concentration). The position of the pn junctions 15 is determined by the intersection between the background (n-type carrier concentration) of the MQW absorption layer 3 and the p-type impurity Zn concentration profile. The impurity (Zn) selectively diffused from the surface of the InP cap layer 4 may be provided with a distribution in which the carrier concentration rapidly decreases from 1e18 cm⁻³ to 9.9e18 cm⁻³ in the InP cap layer-side region to 5e16 cm⁻³ or less in the InP substrate-side region in the diffusion concentration distribution control layer. This can easily make ohmic contact between the pixel electrodes 11 and the surfaces of the p-type regions 6 and maintain good crystal quality of MQW while securing good conductivity in a region immediately below the pixel electrodes together with the low band gap energy specific to InGaAs.

The density of the pixels P may be, for example, 320×256 (about 8 tens of thousands and 2 thousands of pixels) at a pitch of 30 μm.

A detection device 10 shown in FIG. 3B is basically the same as in FIG. 3A. A difference lies only in the structure of the ground electrode 12. In the detection device 10 shown in FIG. 3B, the ground electrode (n-side electrode) 12 of a light-receiving element array 50 faces a ground electrode 72 of CMOS 70 of ROIC, both ground electrodes being conductively connected through a bonded bump 9, 39. In the light-receiving element array 50, the ground electrode 12 includes an electrode portion 12a and a wiring electrode 12b and is conductively connected to an electrode structure provided in a region where p-type impurity is not selectively diffused, the bump 9 being provided on the electrode structure. Of course, the ground electrode 12 is positioned in the region K near the periphery, and thus the bump 9 on the ground electrode 12 has a larger diameter and a lower height as compared with the bumps in a central region (not shown). FIGS. 3A and 3B each show a portion of the detection device 10 in the region K near the outer periphery.

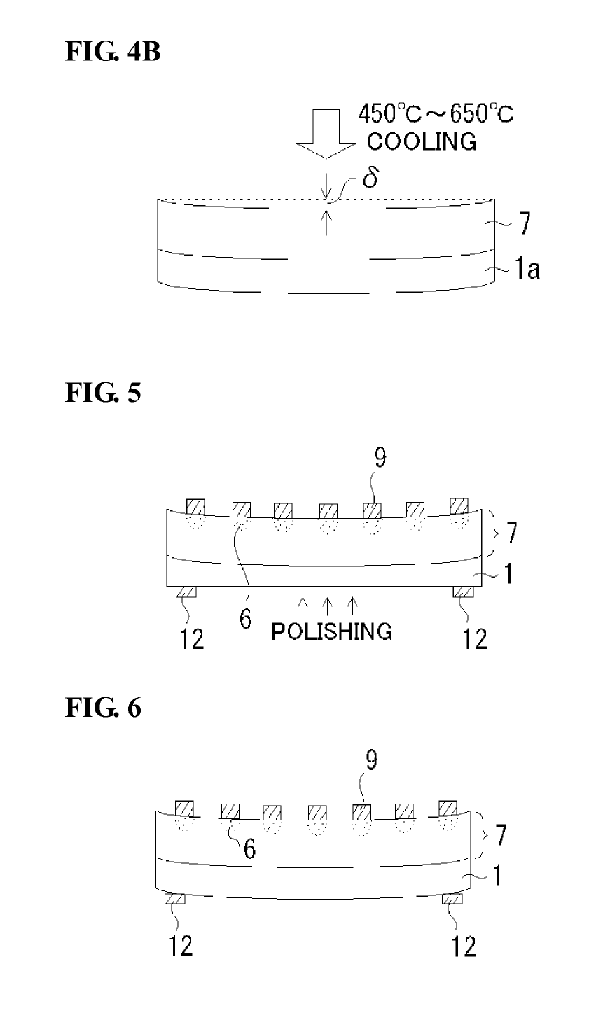

Next, a manufacturing method is described. First, as shown in FIG. 4A, the epitaxial stacked structure 7 including the absorption layer is grown on an InP wafer (epitaxial wafer) 1a in the temperature range of 450° C. to 650° C. As the InP wafer 1a, for example, a 2-inch diameter wafer is used.

When the absorption layer 3 is composed of type 2 MQW, the light-receiving element array 50 is manufactured by the process described below.

First, as shown in FIG. 4A, for example, an n-type InGaAs buffer layer 2 (or an n-type InP buffer layer 2) having a thickness of 2 μm is grown on the InP wafer 1a. Next, the absorption layer 3 of type 2 MQW composed of (InGaAs/GaAsSb), (InGaAsN/GaAsSb), (InGaAsNP/GaAsSb), or (InGaAsNSb/GaAsSb) is formed. Although the growing method is not particularly limited, for example, MBE (Molecular Beam Epitaxy) method or MOVPE (Metal-organic Vapor Phase Epitaxy) method can be used.

Although the case of (InGaAs/GaAsSb) is described below, description below is true for the others. As the InP wafer 1a, an off-angle substrate which is tilted from (100) in the [111] direction or the [11-1] direction at 5 degrees to 20 degrees may be preferably used. More preferably, the substrate is tilted from (100) in the [111] direction or the [11-1] direction at 10 degrees to 15 degrees. By using such a substrate with a large off-angle, the epitaxial stacked structure 7 having a low defect density and good crystal quality can be formed.

In order to achieve lattice matching with InP, InGaAs has the composition In_{0.53}Ga_{0.47}As, and GaAsSb has the composition GaAs_{0.52}Sb_{0.48}. Consequently, a degree of lattice matching ((|Δa/ao| wherein a is a lattice parameter, ao is a lattice parameter of InP, and Δa is a difference in lattice parameter from InP) of 0.002 or less can be achieved.

The thickness of the InGaAs layer is 5 nm, the thickness of the GaAsSb layer is 5 nm, and the number of pairs is, for example, 250. Next, for example, an InGaAs layer having a thickness of 1 μm is epitaxially grown on the absorption layer 3 to form the diffusion concentration distribution control layer used for Zn selective diffusion. Finally, for example, an InP cap layer 4 having a thickness of 1 μm is epitaxially grown.

As described later, when the ground electrode 12 is formed on the InP substrate 1, the InP substrate 1 used contains n-type impurity such as Si at a concentration higher than a predetermined level in order to make ohmic contact. For example, n-type dopant such as Si may be contained at about 1e17 cm⁻³ or more.

The absorption layer 3 of type 2 MQW composed of InGaAs/GaAsSb, the InGaAs diffusion concentration distribution control layer and the InP cap layer 4 are preferably undoped, but may be doped with n-type dopant such as Si in a trace amount (for example, about 2e15 cm⁻³).

Then, the epitaxial wafer 1a is cooled to room temperature. That is, the epitaxial wafer 1a is taken out from a growth chamber in which the epitaxial stacked structure 7 is grown. At this time, as shown in FIG. 4B, the epitaxial wafer 1a is entirely warped so that the surface of the epitaxial stacked structure 7 is warped into a concave shape or bowl-like shape. As shown in FIG. 4B, the degree of warp is δ=about several μm to 100 μm for the epitaxial wafer 1a, depending on the degree of lattice matching between the InP substrate and the absorption layer.

Next, the SiN selective diffusion mask pattern 36 is formed, and p-type impurity is introduced by selective diffusion within a limited planar region of the light-receiving element inside the peripheral portion, thereby forming the p-type regions 6 (refer to FIGS. 5 and 6). The selective diffusion is performed so that the p-type regions 6 extend into the absorption layer 3 of type 2 MQW composed of InGaAs/GaAsSb. The pn junction 15 is formed at the front end of each of the p-type regions 6. In addition, a Zn concentration distribution is formed near each of the pn junctions 15 so as to show graded type junction.

The pn junctions 15 are interpreted in the following wide sense. The pn junctions 15 include junctions formed between the p-type regions 6 formed by diffusive introduction and regions (referred to as “i-regions”) opposite to the p-type regions 6 in the absorption layer 3, the i-regions having such a low impurity concentration that it is regarded as an intrinsic semiconductor. In other words, the pn junctions may be pi functions and further include the case where the p concentration at the pi junctions is very low.

The pn junctions 15 are not exposed in the end surfaces of the light-receiving elements. The p-type regions are limited to the inside of the pixels P, and a plurality of pixels P are arranged without element separation trenches so that the adjacent pixels P are securely separated (refer to FIGS. 3A and 3B). As a result, a leak of photoelectric current is suppressed.

Next, the pixel electrodes 11 (p-side electrodes) on the surfaces of the p-type regions 6 (InP cap layer 4) and the ground electrode 12 on the rear side of the InP substrate 1 are formed. Although not shown in detail in the drawings, the ground electrode 12 is provided not only on the peripheral portion of the epitaxial wafer 1a but also on each of the light-receiving element arrays after individualization as described below. The pixel electrodes 11 are preferably formed using Ti/Pt/Au or Au/Zn/Au/Ti/Au which easily forms ohmic contact with the p-type regions 6. In addition, the ground electrode 12 (electrode portion 12a) is preferably formed using AuGeNi/Ti/Au.

Then, as shown in FIGS. 5 and 6, the bumps 9 are formed. FIG. 5 shows the case where the rear surface of the epitaxial InP wafer 1a warped as described above is planarized by polishing. FIG. 6 shows the case where the epitaxial wafer 1a is maintained in a horizontal position, without being planarized, by controlling the height of support members (not shown) separately arranged.

In both FIGS. 5 and 6, the bumps 9 are disposed on the pixel electrodes (not shown) from a nozzle of an automation apparatus so as to have the same weight and the same shape. Namely, in this step, all the bumps 9 have the same shape.

The bumps 9 may be anything as long as they are composed of a metal which is easily subjected to pressure bonding regardless of being a single-phase metal or an alloy. For example, the bumps 9 can be composed of indium (In), tin (Sn), an indium alloy, or a tin alloy.

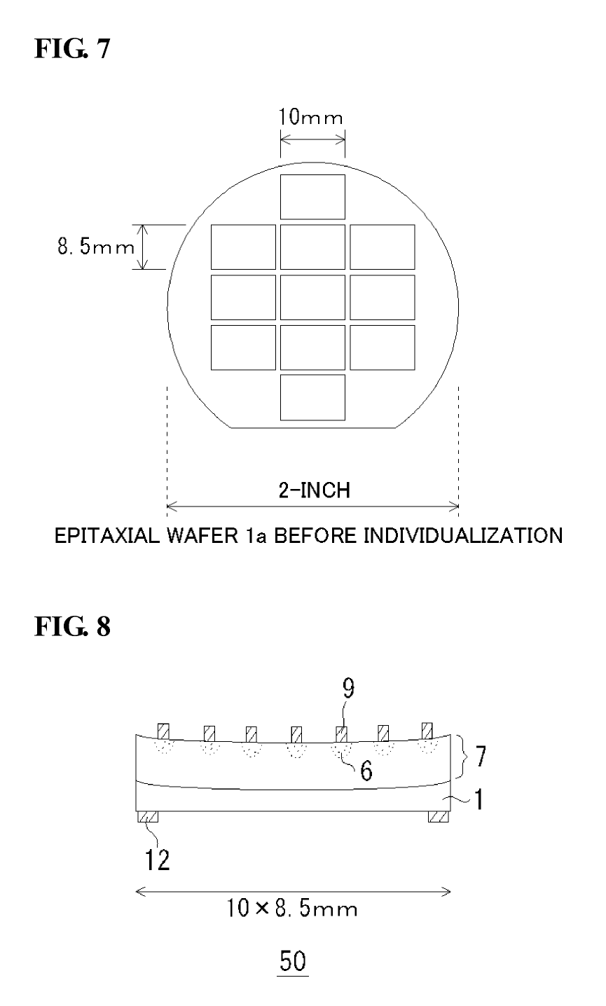

FIG. 7 is a drawing showing the epitaxial wafer 1a formed as described above. Then, the epitaxial wafer 1a is individualized to form the light-receiving element arrays (chips) 50. In an example shown in FIG. 7, 11 light-receiving element arrays 50 can be formed from a 2-inch diameter wafer. The InP wafer 1a is not limited to the 2-inch diameter wafer and any desired size may be used. Individualization may be performed by an ordinary method.

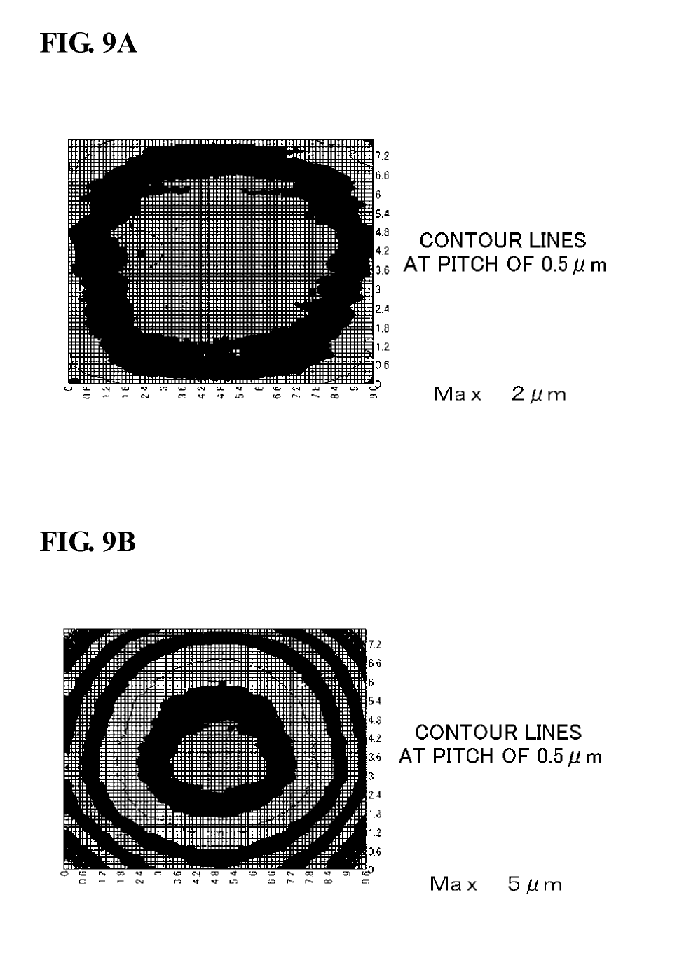

FIG. 8 is a drawing showing the individual light-receiving element array (chip) 50 after individualization. Even after individualization, the warp of the epitaxial wafer 1a is retained. FIGS. 9A and 9B show examples of the degree of warp of a bowl-shaped curved surface. The figures show the respective cases of large warp and small warp of a rectangular shape of 8.5 μm in length and 10 μm in width after individualization. FIGS. 9A and 9B each show contour lines at a pitch of 0.5 μm in the surface of the epitaxial stacked structure with a central portion positioned at the bottom. In FIG. 9A, a total of four contour lines (the 4th line is slightly observed at the corners) are drawn, the height at the corners is higher than the center by about 2 μm. In FIG. 9B, ten contour lines are observed, and the height at the corners is higher than the center by 5 μm.

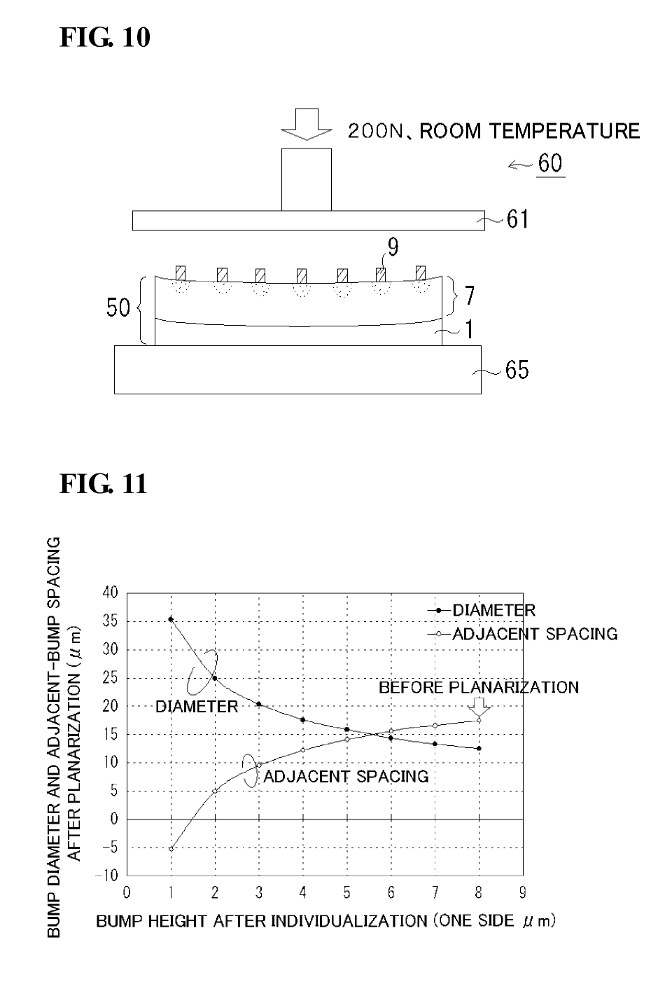

FIG. 10 is a drawing showing the state in which a plate 61 is applied using a planarization apparatus 60 on the bumps 9 of the light-receiving element array 50 arranged on a lower stage 65. The push-down load of the plate 61 is, for example 200 N. The planarization of the bumps 9 by pressing can provide the light-receiving element array 50 shown in FIG. 1. The light-receiving element array 50 has the following characteristics:

(1) The surface of the epitaxial stacked structure 7 is an upwardly (outwardly) concaved surface.

(2) The bumps 9 in the region K near the periphery have a larger diameter and a lower height than those of the bumps 9 in the central region.

(3) The top surfaces 9s of the bumps 9 are flat surfaces all of which are arranged in a plane H. That is, the top surfaces 9s of all bumps 9 are placed on a plane defined by a surface of a plate.

FIG. 11 is a graph showing the relation (simulation) between the height (abscissa) of the bumps 9 and the diameter and adjacent-bump spacing (ordinate) as a result of deformation by pushing planarization. As shown in FIG. 11, deformation is started from the relation before planarization. As the height of the pumps 9 is decreased by pushing, the diameter of the pumps 9 is increased, and the adjacent spacing is decreased. The bumps 9 in the region K near the periphery are pushed by a longer length and thus more decreased in height. Conversely, the height of the bumps 9 in the central region C is substantially the same as or slightly shorter than that before planarization. As a result, the bumps 9 near the periphery are pushed more and decreased in height, resulting in a large diameter and a smaller adjacent spacing. For example, when an average warp shown in FIGS. 9A and 9B is 3.5 μm, the bumps in the peripheral portion are pushed by 3.5 μm or more so that the bumps in the peripheral portion are arranged at the same height as the bumps in the central portion. FIG. 11 indicates that by pushing by at least 3.5 μm, the diameter of the bumps 9 in the peripheral region is increased to at least 17 μm from about 12 μm. This increase in diameter and decrease in length are very large from the viewpoint of load bearing.

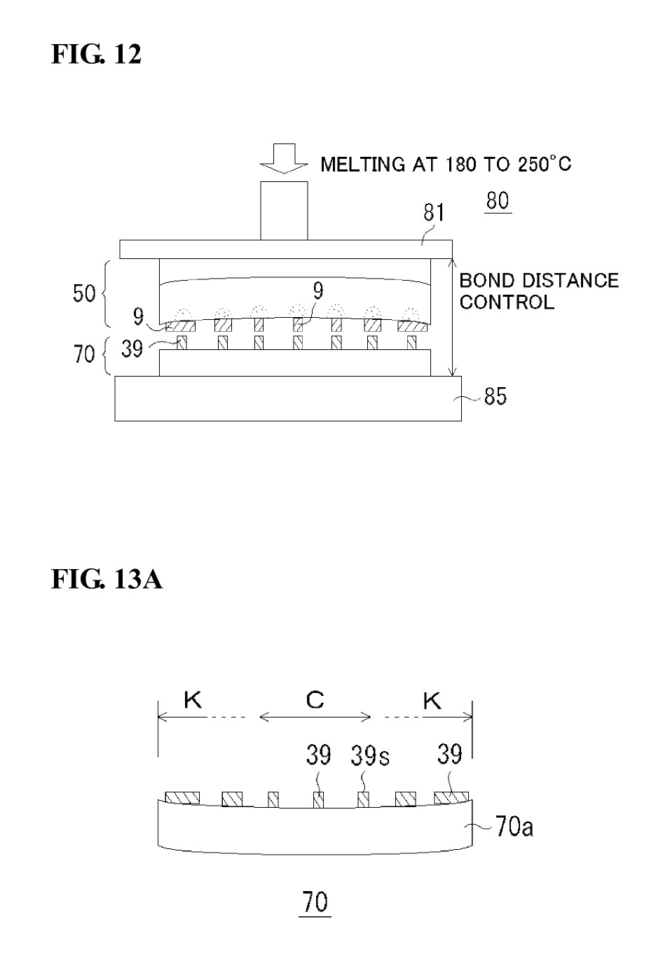

FIG. 12 is a drawing showing the state where the bumps 9 of the light-receiving element array 50 are bonded to the bumps 39 of the CMOS 70 using a bonding apparatus 80. The CMOS 70 is fixed to a lower flat stage 85, and the light-receiving element array 50 is fixed to an upper stage 81. Bonding is performed under control of a bond distance between both members. The bumps are generally melt-bonded by heating at 180° C. to 250° C. but may be pressure-bonded at room temperature. As a result, the detection device 10 shown in FIG. 2A can be manufactured.

### Second Embodiment

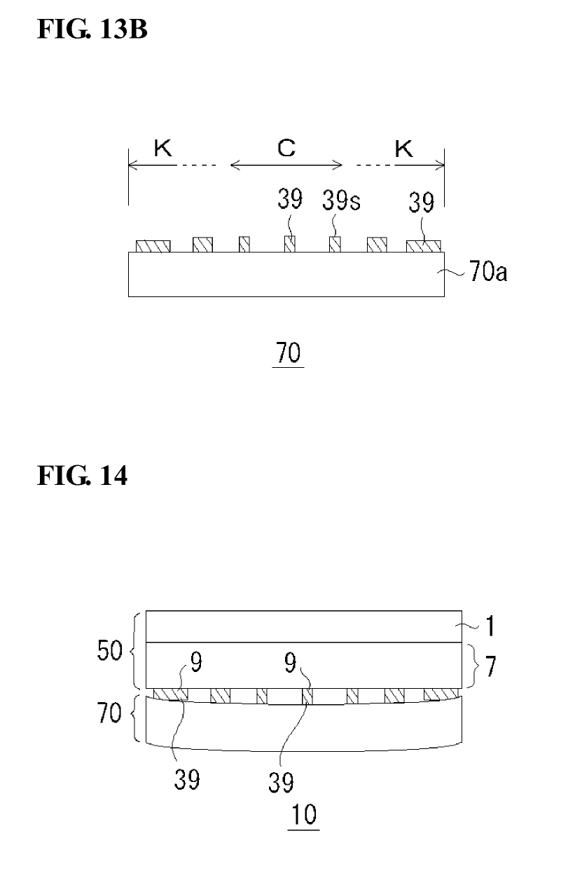

FIGS. 13A and 13B are drawings each showing a read-out integrated circuit 70 formed on silicon according to a second embodiment of the present invention. FIG. 13A is a drawing showing the case where the surface is entirely concavely warped in a bowl-like shape, and FIG. 13B is a drawing showing the case where the entire warp is eliminated to restore flatness. In both FIGS. 13A and 13B, the CMOS 70 includes a CMOS body 70a provided with read-out electrodes (not shown) and bumps 39 provided on the read-out electrodes.

In FIGS. 13A, the top surfaces 39s of the bumps 39 are arranged at the same height. On the other hand, in FIG. 13B, the height of the top surfaces 39s of the bumps 39 in the central region C are higher than the top surfaces 39s of the bumps 39 in the region K near the periphery (positioned away from the surface of the CMOS body 70a). This results from springback (restoration).

However, both cases are common in the point that the bumps 39 in the region K near the periphery have a larger diameter and a shorter length than those of the bumps 39 in the central region C. In addition, in both cases, the top surfaces 39s are planar.

FIG. 14 is a drawing showing a detection device 10 including combination of the CMOS 70 shown in FIG. 13A or 13B and a light-receiving element array 50. The configuration of bumps 39 of the CMOS 70 is similar to that of the bumps 9 of the light-receiving element array 50 according to the first embodiment, but the warp shown in FIG. 2A is inverted. The bonded bumps 39, 9 in the region K near the periphery have a larger diameter and a shorter length than the bonded bumps 39, 9 in the central region C. Therefore, even when thermal stress occurs, connection failure can be prevented by suppressing deformation, and a high-quality detection device with no defect can be provided.

In addition, the top surfaces 39s of the bumps 39 of the CMOS 70 are made planar by pushing, and mismatch is little caused regardless of the shape of the bumps 9 of the other member to be bonded to the CMOS 70, thereby permitting stable bonding.

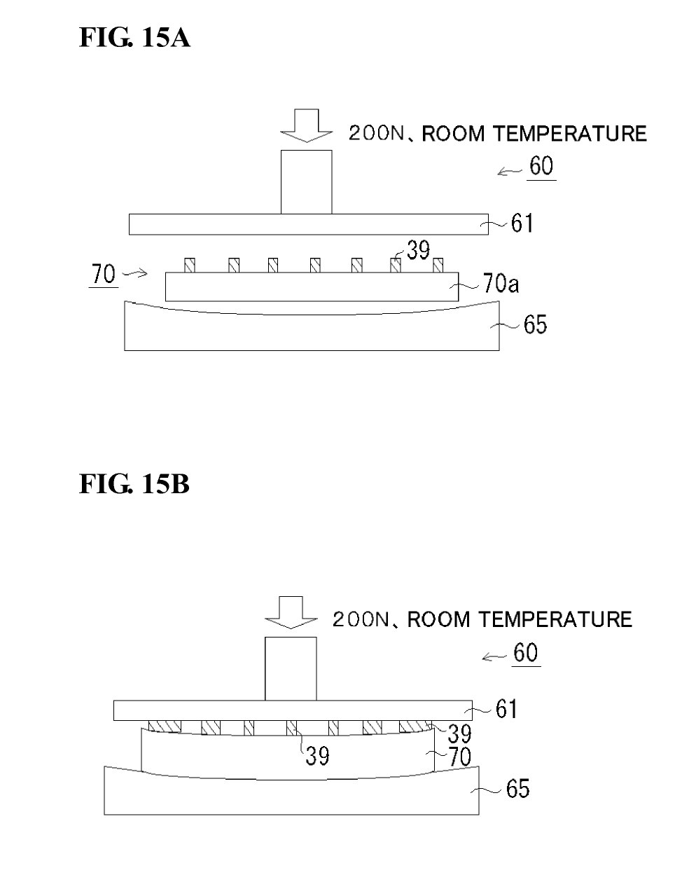

FIGS. 15A and 15B are drawings each showing a method for manufacturing a CMOS 70 serving as the read-out integrated circuit shown in FIG. 13A or 13B. In FIG. 15A, a planarization device 60 includes a lower stage 65 having a bowl-like concaved surface and a pressure portion having a plate 61 provided in an upper portion so that the CMOS 70 is inserted between the lower stage 65 and the plate 61. Pressing is performed by, for example, applying a load of 200 N at room temperature. The plate 61 is pushed toward the bumps 39 while the CMOS 70 is supported by the lower stage 65 having a bowl-like concaved surface. As a result, the CMOS 70 shown in FIG. 13A or 13B can be manufactured according to the restoration property of the whole circuit formed on silicon.

### Third Embodiment

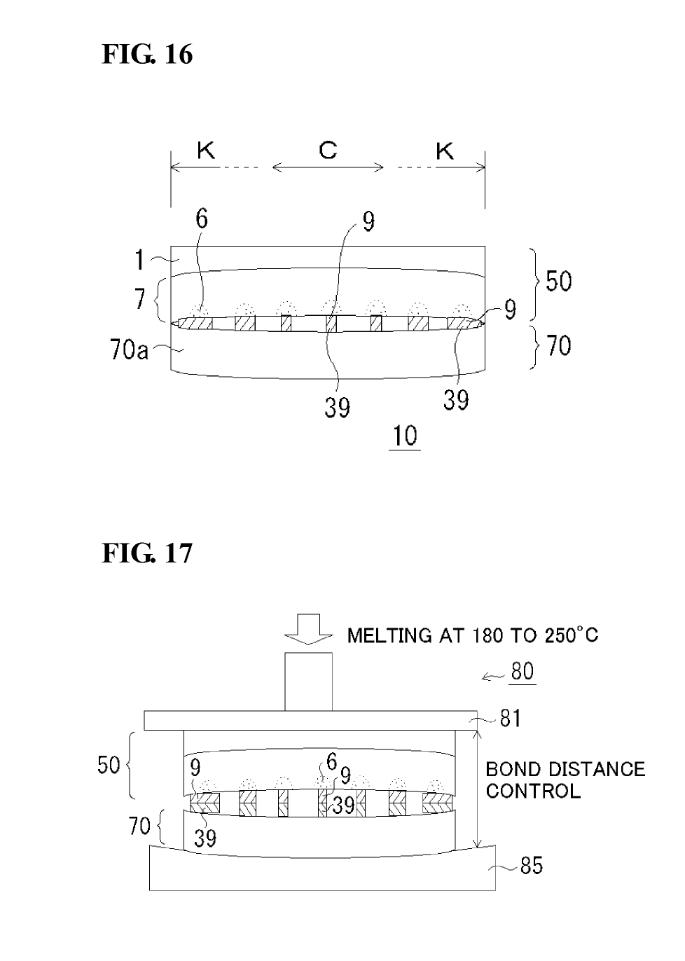

FIG. 16 is a drawing showing a detection device 10 according to a third embodiment of the present invention. This embodiment is characterized by using the light-receiving element array 50 of the first embodiment (refer to FIG. 1) and the CMOS 70 of the second embodiment (refer to FIG. 13A or 13B). That is, in the detection device 10 shown in FIG. 16, both the light-receiving element array 50 and the CMOS 70 have concaved surfaces which face each other. In addition, the bumps 9, 39 in the region K near the periphery have a larger diameter and a shorter length than the bonded bumps 9, 39 in the central region C. In more detail, the bonded bumps 9, 39 are increased in diameter and decreased in length from the center to the periphery with some variation, but strictly not in a linear manner. The bonded bumps 9, 39 have the above-described biased configuration. In particular, in this embodiment, the bumps 9 and 39 of both the light-receiving element array 50 and the CMOS 70 have the above-described configuration so that the bonded bumps 9, 39 near the periphery tend to be significantly biased to have a larger diameter and a shorter length.

Therefore, even when a larger thermal load is applied to the bumps 9 and 39 in the region near the periphery, large stress is not applied. Thus, the bonded bumps 9, 39 are not deformed or are deformed to a smaller extend than in the first and second embodiments. As a result, bonding failure is not stably produced, and a high-quality detection device can be provided.

FIG. 17 is a drawing showing a method for manufacturing the detection device 10 of this embodiment using a bonding device 80. A lower stage 85 which supports the CMOS 70 has a blow-like curved surface following the warp of the CMOS 70. The CMOS 70 is placed on the lower stage 85, and the bumps 9 on the pixel electrodes of the light-receiving element array 50 fixed to an upper stage 81 are aligned with the bumps 39 on the read-out electrodes and bonded thereto by pressing and heating. The heating temperature is preferably about 180° C. to 250° C. according to the melting temperature of the material (indium or the like) of the bumps 9 and 39.

Although the embodiments and examples are described above, the embodiments and examples disclosed above are only illustrative, and the scope of the present invention is not limited by these embodiments. The scope of the present invention is determined by the claims and further includes meanings equivalent to the claims and modifications within the scope.

What is claimed is:

1. A detection device comprising:
a light-receiving element array including pixel electrodes arranged therein and a bump disposed on each of the pixel electrodes; and
a read-out integrated circuit (ROIC) including read-out electrodes arranged therein and a bump disposed on each of the read-out electrodes, the bumps of the light-receiving element array being bonded to the bumps of the read-out integrated circuit,
wherein at least one of the light-receiving element array and the read-out integrated circuit has a concaved surface facing the other, and
the bonded bumps positioned in a region near the periphery of the arrangement region of the bonded bumps have a larger diameter and a lower height than those of the bumps positioned in a central region.

2. The detection device according to claim 1,
wherein the light-receiving element array includes a semiconductor substrate and an epitaxial stacked structure formed on the semiconductor substrate and including an absorption layer;
a pixel region having ohmic contact with the pixel electrodes is formed by selectively diffusing an impurity from the surface of the epitaxial stacked structure to form a pn junction for each pixel; and
the absorption layer satisfies the condition of lattice matching with the semiconductor substrate, |‘a’−ao|/ao≦0.002 (wherein ‘a’ is a lattice parameter of the absorption layer, and ao is a lattice parameter of the semiconductor substrate).

3. The detection device according to claim 2,
wherein the absorption layer is configured to have a multi-quantum well structure (MQW);
a diffusion concentration distribution control layer is disposed in contact with the pixel electrode-side surface of the absorption layer;
the diffusion concentration distribution control layer is made of a material having a smaller band gap than the semiconductor substrate; and
the concentration of the impurity element in the diffusion concentration distribution control layer decreases stepwisely from a concentration region on the pixel electrode side to a low concentration region on the semiconductor substrate side.

4. The detection device according to claim 3,
wherein the semiconductor substrate is an InP substrate;
the multi-quantum well structure is type 2 composed of any one of GaAsSb/InGaAs, GaAsSb/InGaAsN, GaAsSb/InGaAsNP, and GaAsSb/InGaAsNSb, and the band gap wavelength including a sub-band is 1.65 μm or more and 3 μm or less;
the impurity element is zinc (Zn);
the diffusion concentration distribution control layer is composed of InGaAs;
the impurity concentration in the absorption layer is 5e16 cm⁻³ or less; and
the impurity concentration in the diffusion concentration distribution control layer decreases from 1e18 cm⁻³ or more and 9.9e18 cm⁻³ or less in the pixel electrode-side region to 5e16 cm⁻³ or less in the InP substrate-side region.

5. A light-receiving element array comprising:
pixel electrodes arranged therein and a bump disposed on each of the pixel electrodes; and
an epitaxial layer on which the pixel electrodes are arranged and which has a concaved surface,
wherein the top surfaces of the bumps are arranged in a plane, and
the tops of the bumps disposed in a region near the periphery of the arrangement region have a larger diameter and a lower height than the bumps disposed in a central region.

6. The light-receiving element array according to claim 5, further comprising:
a semiconductor substrate; and
an epitaxial stacked structure formed on the semiconductor substrate and including an absorption layer,
wherein a pixel region where the pixel electrodes make ohmic contact is formed by selective diffusion of an impurity from the surface of the epitaxial stacked structure so as to form a pn junction for each of the pixels; and
the absorption layer satisfies the condition of lattice matching with the semiconductor substrate, |‘a’−ao|/ao≦0.002 (wherein ‘a’ is a lattice parameter of the absorption layer, and ao is a lattice parameter of the semiconductor substrate).

7. The light-receiving element array according to claim 6,
wherein the absorption layer is configured to have a multi-quantum well (MQW) structure;
a diffusion concentration distribution control layer is disposed in contact with the pixel electrode-side surface of the absorption layer;
the diffusion concentration distribution control layer is made of a material with a smaller band gap than that of the semiconductor substrate; and
the concentration of the impurity element in the diffusion concentration distribution control layer decreases stepwisely from a concentration region on the pixel electrode side to a low concentration region on the semiconductor substrate side.

8. The light-receiving element array according to claim 7,
wherein the semiconductor substrate is an InP substrate;
the multi-quantum well structure is type 2 composed of any one of GaAsSb/InGaAs, GaAsSb/InGaAsN, GaAsSb/InGaAsNP, and GaAsSb/InGaAsNSb, and the band gap wavelength including a sub-band is 1.65 μm or more and 3 μm or less;
the impurity element is zinc (Zn);
the diffusion concentration distribution control layer is composed of InGaAs;
the impurity concentration in the absorption layer is 5e16 cm⁻³ or less; and
the impurity concentration in the diffusion concentration distribution control layer decreases from 1e18 cm⁻³ or more and 9.9e18 cm⁻³ or less in the pixel electrode-side region to 5e16 cm⁻³ or less in the InP substrate-side region.

9. A semiconductor chip comprising:
electrodes arranged therein and a bump disposed on each of the electrodes; and
an epitaxial layer on which the electrodes are arranged and which has a concaved surface,
wherein the bumps provided on the electrodes have flat top surfaces and the top surfaces of the bumps disposed in a region near the periphery have a larger diameter and a lower height than those of the bumps disposed in a central region.

10. The semiconductor chip according to claim 9, wherein the semiconductor chip is a read-out integrated circuit, and the electrodes are read-out electrodes.

11. An optical sensor apparatus comprising the detection device according to claim 1.

12. A method for manufacturing a light-receiving element array including pixel electrodes arranged therein, the method comprising:
a step of growing an epitaxial stacked structure on a semiconductor wafer at a temperature of 450° C. or more and 650° C. or less and then cooling the structure to warp the semiconductor wafer along a concaved surface of the epitaxial stacked structure;
a step of forming the pixel electrodes on the surface of the epitaxial stacked structure;
a step of disposing a material of bumps in the same shape and same weight for the pixel electrodes in order to form the bumps on the pixel electrodes;
a step of individualizing the semiconductor wafer to form light-receiving element array chips; and
a step of placing a plate on the bumps of the light-receiving element array and applying a pressure so that the top surfaces of the bumps are arranged in parallel with the surface of the plate.

13. A method for manufacturing a detection device including a light-receiving element array manufactured by the manufacturing method according to claim 12, the method comprising:
preparing a read-out integrated circuit (ROIC) including read-out electrodes corresponding to the respective pixel electrodes of the light-receiving element array;
forming a bump on each of the read-out electrodes, and
bonding the bump of each of the pixel electrodes of the light-receiving element array to the bump of each of the read-out electrodes of the read-out integrated circuit by pressure bonding or heating fusion.

14. The method for manufacturing a detection device according to claim 13, comprising, after forming the bump on each of the read-out electrodes of the read-out integrated circuit:
disposing the read-out integrated circuit on a support having a concaved surface; and
placing a plate on the bumps of the read-out electrodes and applying pressure to bond the bump of each of the pixel electrodes of the light-receiving element array to the bump of each of the read-out electrodes of the read-out integrated circuit.

15. The method according to claim 14, wherein the concaved surface of the support is formed so as to rise at a rate of 2 μm to 10 μm per 10 mm in a radial direction from the center to the periphery in such a manner that an outer portion more rises than a central portion.

16. A method for manufacturing a read-out integrated circuit formed on a semiconductor substrate and including read-out electrodes arranged therein, the method comprising:
a step of forming a bump on each of the electrodes of the read-out integrated circuit;
a step of preparing a support having a concaved surface; and
a step of disposing the read-out integrated circuit having the bumps formed thereon on the support and pressing the bumps by applying pressure to a plate disposed thereon.

17. A method for manufacturing a detection device including a read-out integrated circuit manufactured by the method for manufacturing a read-out integrated circuit according to claim 16, the method comprising:
preparing a light-receiving element array having pixel electrodes which correspond to the respective read-out electrodes of the read-out integrated circuit;
forming a bump on each of the pixel electrodes; and
bonding the bumps of the read-out electrodes of the read-out integrated circuit to the bumps of the pixel electrodes of the light-receiving element array by pressure bonding or heat melting.

18. An optical sensor apparatus comprising the light-receiving element array according to claim 5.

19. An optical sensor apparatus comprising the semiconductor chip according to claim 9.
